(19) United States
(12) Patent Application Publication
(10) Pub. No.: US 2026/0304735 A1
(43) Pub. Date: Oct. 1, 2026

(54) SILICON-ON-INSULATOR (SOI) REPLACEMENT FOR 4F2 DRAM USING SACRIFICIAL SILICON GERMANIUM AND BOTTOM-UP DIELECTRIC

(71) Applicant: Applied Materials, Inc., Santa Clara, CA (US)

(72) Inventors: Zhijun CHEN, San Jose, CA (US); Raghuveer S. MAKALA, Campbell, CA (US)

(73) Assignee: Applied Materials, Inc., Santa Clara, CA (US)

(21) Appl. No.: 19/094,792

(22) Filed: Mar. 28, 2025

(51) Int. Cl. H10B 12/00; H01L 21/762; H01L 21/768

(52) U.S. Cl. CPC H10B 12/05; H10W 10/014; H10W 10/17; H10W 20/076

(57) ABSTRACT

Silicon substrates may be used with a silicon germanium layer on the substrate instead of Silicon-on-Insulator (SOI) substrates. Shallow Trench Isolation (STI) trenches may include a dielectric such as silicon oxide at the bottom of the trench, with the remainder of the trench filled with silicon germanium or other materials that can be dry etched with silicon in a silicon etch chemistry, and that can also be removed selective to silicon by other dry or wet etch methods. Channel etches may then be configured to remove the silicon and silicon germanium while leaving the silicon oxide intact and avoids etching silicon and oxide simultaneously. The dielectric may also provide structural support throughout the manufacturing process. The silicon germanium layer adjacent to the silicon substrate may then be removed and replaced with a stronger layer stop layer for a backside etch.

### TECHNICAL FIELD

This disclosure generally describes designs for advanced memory devices, such as 4F² dynamic random-access memory (DRAM) arrays. More specifically, this disclosure describes DRAM manufacturing techniques that utilize silicon germanium layers.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries. Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density.

### BRIEF SUMMARY

In some embodiments, a method of forming a DRAM structure may include forming a silicon germanium layer over a first silicon-containing layer; forming a second silicon-containing layer over the silicon germanium layer; and etching an isolation trench between adjacent locations for DRAM devices in the DRAM structure. The isolation trench may be etched through the second silicon-containing layer, through the silicon germanium layer, and into the first silicon-containing layer. The method may also include forming a dielectric in the isolation trench. The dielectric may extend up from a bottom of the isolation trench, through the silicon germanium layer, and into the second silicon-containing layer.

In some embodiments, a method of forming a DRAM structure, may include receiving a semiconductor structure that may include silicon between adjacent gate regions for DRAM devices in the DRAM structure. The silicon may include trenches filled at least in part with silicon germanium. The method may also include performing a channel etch in areas between the adjacent gate regions to remove the silicon and the silicon germanium.

In some embodiments, a method of forming a DRAM structure may include receiving a semiconductor structure comprising trenches etched between adjacent gate regions for DRAM devices in the DRAM structure. The trenches may include a layer of silicon germanium at a bottom of the trenches. The method may also include removing the layer of silicon germanium at the bottom of the trenches; and forming a layer of silicon nitridea stop layer at the bottom of the trenches to replace the layer of silicon germanium.

In any embodiments, any and/or all of the following features may be implemented in any combination and without limitation. The first silicon-containing layer may include a silicon substrate. Forming the dielectric in the isolation trench may include using a chemical vapor deposition (CVD) process to gap-fill the isolation trench with silicon dioxide. Forming the dielectric in the isolation trench may also include performing an etch to remove the dielectric out of the isolation trench, and stopping the etch before the dielectric is below the second silicon-containing layer. Forming the dielectric in the isolation trench may include using a bottom-up fill process to selectively deposit the dielectric at the bottom of the isolation trench until the dielectric extends above the silicon germanium layer. The method may also include, after forming the dielectric in the isolation trench, filling the isolation trench above the oxide with silicon germanium. A concentration of germanium in the silicon germanium filling the isolation trench above the oxide may be different from a concentration of germanium in the silicon germanium layer. The method may also include, after filling the isolation trenches above the dielectric with silicon germanium, performing a back gate etch to form a back gate trench that is orthogonal to the isolation trench. The back gate etch need not remove the dielectric where the back gate trench intersects with the isolation trench. The back gate etch may extend at least down to a bottom of the silicon germanium layer. The trenches may also be filled at least in part with a dielectric at a bottom of the trenches, and the silicon germanium may fill a remaining portion of the trenches above the dielectric at the bottom of the trenches. The semiconductor structure may also include a layer of silicon germanium orthogonal to the trenches and proximate to a bottom of the trenches. The layer of silicon germanium that is orthogonal to the trenches may include a different germanium concentration than the silicon germanium that fills the trenches, such that the layer of silicon germanium acts as an etch stop when performing the channel etch. The method may also include removing the layer of silicon germanium; and forming a layer of silicon nitride to replace the layer of silicon germanium. The method may also include removing a silicon substrate underneath the layer of silicon nitridestop layer, where the stop layer of silicon nitride may act as a stop layer for a process that removes the silicon substrate, and the stop layer comprises silicon nitride. The semiconductor structure may also include a dielectric at the bottom of the trenches, where the dielectric may provide a structural support for the adjacent gate regions when the layer of silicon germanium is removed. Removing the layer of silicon germanium at the bottom of the trenches may also include removing silicon germanium under the gate regions using a wet etch process or an isotropic dry etch process. Forming the stop layer of silicon nitride at the bottom of the trenches may include conformally forming a gate oxide on exposed areas of the semiconductor structure; and performing a bottom-up fill process to selectively form the stop layer of silicon nitride only at the bottom of the trenches over or under the gate oxide.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of an exemplary processing chamber, according to some embodiments.

FIGS. 2A-2B illustrate top and perspective views of an 4F² memory array, according to some embodiments.

FIG. 3 illustrates a method of forming a DRAM structure, according to some embodiments.

FIGS. 4A-4F illustrate incremental steps for forming a semiconductor structure for a DRAM array, according to some embodiments.

FIGS. 5A-5F illustrate incremental structures to form the back gate region, according to some embodiments.

FIGS. 6A-6B illustrates flowcharts of methods for further forming a DRAM structure, according to some embodiments.

FIGS. 7A-7F illustrate example incremental structures to finish forming the gate region, according to some embodiments.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, advanced memory structures, including vertical cell structures such as 4F² DRAM, and other devices having complex features come with their own challenges. Existing processes use expensive silicon-on-insulator (SOI) substrates. Vertical channel formation often requires either a very complicated bi-directional etch which separates the channel materials in both X and Y directions at the same time, or separate X and Y etches which requires etching both channel material and isolation dielectrics (e.g. silicon oxide) at the same time during the second etch. When performing the bi-directional etch, the geometry of existing devices leaves silicon stringers that are difficult to remove. When performing separate X & Y etches, the selectivity of the liner-type hard mask may also not be higher enough. Finally, existing backside etch stop layers are often not robust enough for backside removal processes.

The present technology overcomes these and other problems by using silicon substrates with a silicon germanium layer on the substrate instead of SOI substrates. Shallow-Trench-Isolation (STI) trenches may include a dielectric at the bottom of the trench, with the remainder of the trench filled with silicon germanium or other materials that can be dry etched with silicon in a silicon etch chemistry, and that can also be removed selective to silicon by other dry or wet etch methods. Channel etches may then be configured to remove the silicon and silicon germanium while leaving the oxide intact and avoids etching silicon and oxide simultaneously. The dielectric may also provide structural support throughout the manufacturing process. The silicon germanium layer adjacent to the silicon substrate may then be removed and replaced with a stronger layer, such as a silicon nitride layer or other materials, such as SiO, SiON, SiCON, SiOC, SiCN, and/or other similar materials to act as a backside etch stop.

Although the remaining disclosure will routinely identify specific deposition and etch processes utilized for forming vertical cell access array transistors (VCAATs), such as a 4F² DRAM device, it will be readily understood that the systems and methods are equally applicable to other memory devices, including 6F² DRAM arrays, 3D NAND, and/or 3D DRAM device, junction-less SONOS memory, floating body cell memory, oxide semiconductor memory, ferroelectric memory, and other devices having high aspect ratio features, and orientations thereof, as well as processes for forming such devices. Accordingly, the technology should not be considered to be so limited as for use with these specific devices or systems alone. The disclosure will discuss one possible semiconductor device that may include one or more components, utilizing one or more power lines and/or signal lines according to embodiments of the present technology before additional variations and adjustments to this apparatus according to embodiments of the present technology are described.

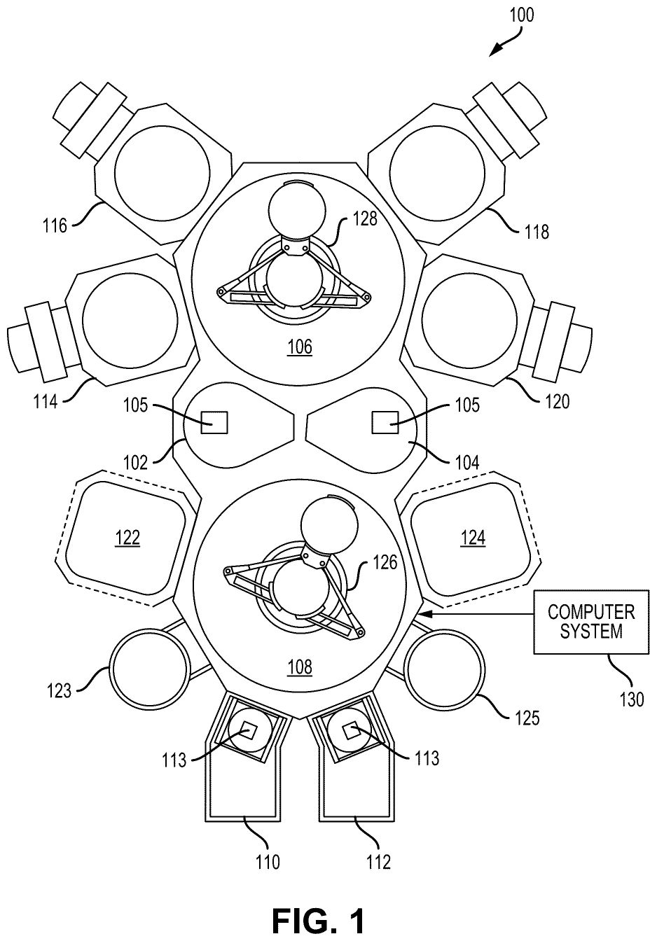

FIG. 1 illustrates a top plan view of a multi-chamber processing system 100, which may be specifically configured to implement aspects or operations according to some embodiments. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

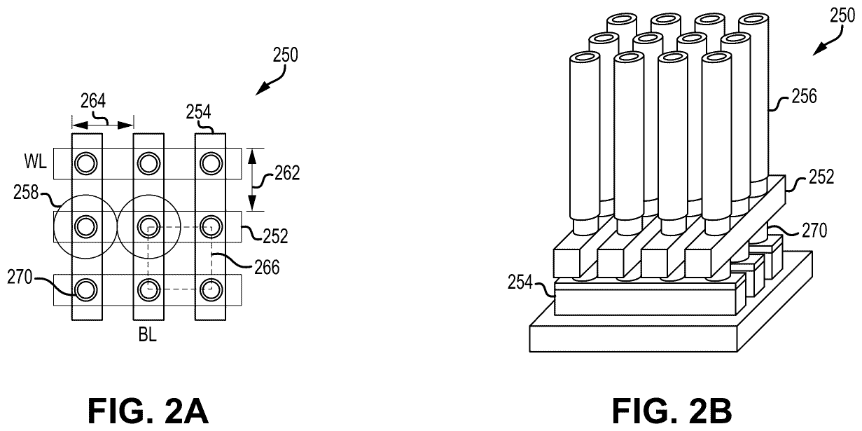

FIGS. 2A-2B illustrate top and perspective views of an 4F² memory array 250, according to some embodiments. The memory array 250 may include a plurality of word lines 252 that are arranged in a first layer over a substrate. The word lines 252 may intersect with a channel of a respective transistor and be conductive traces that are used to select a word line of memory cells in the memory array 250. The memory array 250 may also include a plurality of bit lines 254 that electrically connect to a source/drain region of a respective transistor and be arranged in a second layer over a substrate. The plurality of bit lines may be conductive traces that are used to select a bit line of memory cells in the memory array 250. Activating one of the plurality of bit lines 254 and one of the plurality of word lines 252 may select an individual cell in the memory array 250. The first layer and the second layer may include different metal layers formed at different times during manufacturing process. For example, the first layer with the word lines 252 may be formed above the second layer with the bit lines 254 such that the two layers do not intersect.

A plurality of vertical memory cells may be arranged over intersections between the plurality of word lines 252 and the plurality of bit lines 254. Each of the plurality of vertical memory cells may include a vertical transistor, which may be referred to as a vertical pillar transistor or vertical column transistor. A channel material for the transistor may be formed from a single-crystalline silicon, poly-crystalline silicon, amorphous silicon, silicon carbide, silicon germanium, germanium, an oxide semiconductor, including indium gallium zinc oxide, 2D materials including molybdenum disulfide, gallium nitride, carbon nanotubes, graphene, boron arsenide, combinations thereof, or any other substrates discussed in greater detail herein. Furthermore, dopants may be introduced based upon the device need, for any one or more of the materials discussed herein. This silicon channel may be formed by etching the substrate, as shown in the illustrated embodiments, or may be deposited onto the substrate, depending upon the desired device. Each of the plurality of vertical memory cells may also include a vertical capacitor 256. The vertical memory cell may operate by storing a charge on the vertical capacitors 256 to indicate a saved memory state. However, while FIGS. 2A-2B illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 2A-2B. Thus, it should be understood that any suitable orientation may be utilized with the present technology.

It is useful to characterize the dimensions of the unit cell area 266 for this conventional 4F² memory array for comparison to the simple memory array described below. For example, a capacitor footprint 258 may be defined as a circular area around each vertical capacitor 256. The capacitor footprint 258 may include the horizontal cross-sectional area of the capacitor expanded out until the cross-sectional area contacts a capacitor area from a neighboring memory cell. Assuming that the word line pitch 262 for the plurality of word lines 252 and the bit line pitch 264 for the plurality of bit lines 254 may be defined as 2F. This leads to an overall cross-sectional area of 4F² for a unit cell area 266.

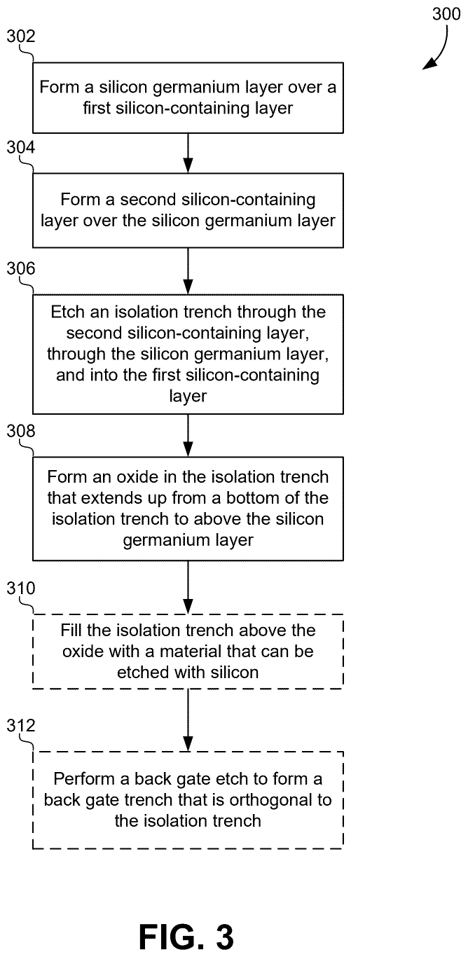

FIG. 3 illustrates a method 300 of forming a DRAM structure, according to some embodiments. The method may be performed in a variety of processing chambers, including processing chamber 100 described above in FIG. 1. Method 300 may include a number of optional operations, which may or may not be specifically associated with various embodiments. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized, as well as other orientations for non-vertical cell transistors. The method 300 may be specifically used in forming a 4F2 DRAM structure. However, the method 300 may also be used in other memory structures as well.

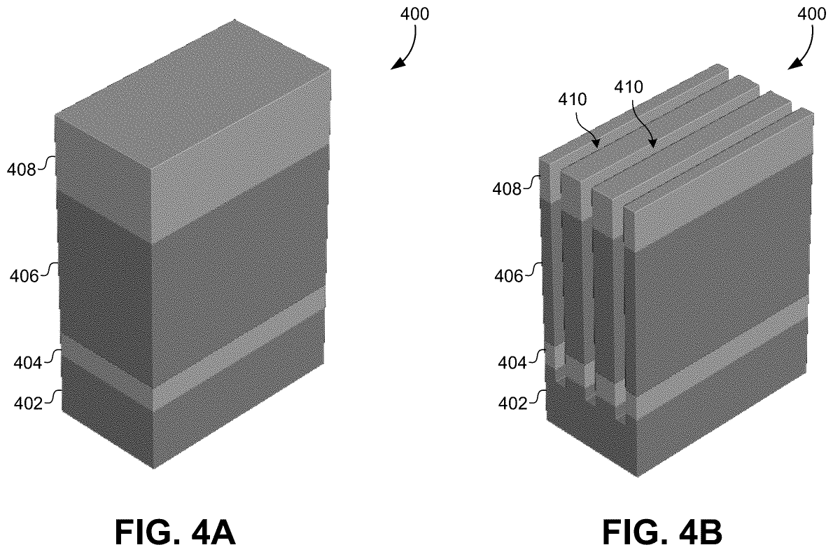

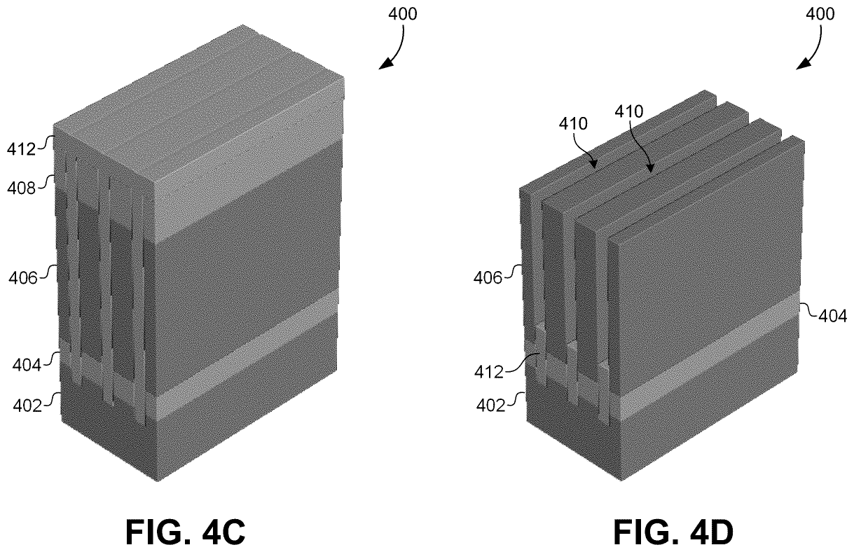

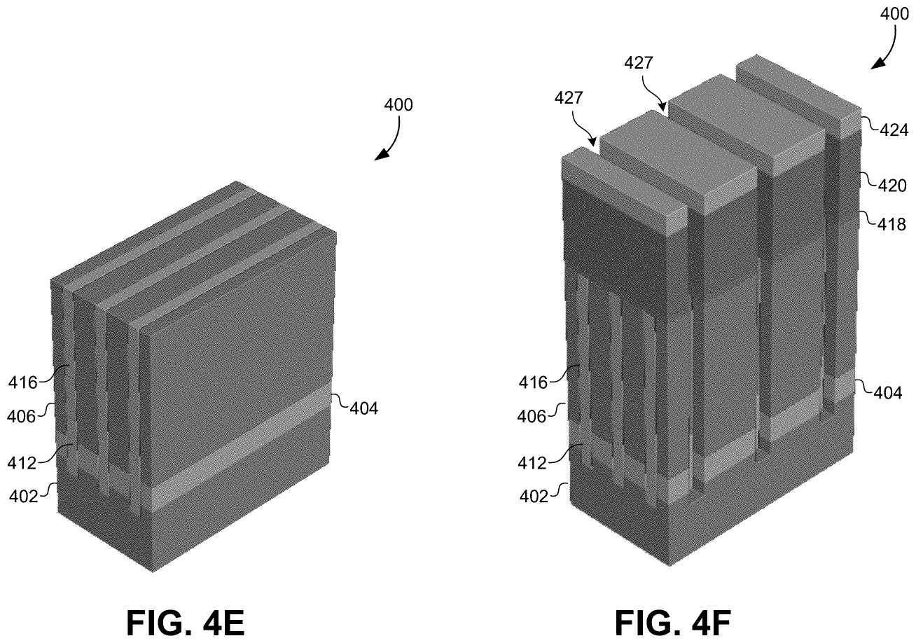

FIGS. 4A-4F illustrate incremental steps for forming a semiconductor structure 400 for a DRAM array, according to some embodiments. The incremental structures illustrated in these figures may represent example structures that may be performed by the operations of method 300. However, the structures are provided only by way of example and are not meant to be limiting. The operations of method 300 may be broader than these example structures, and additional processes and structures may be included in different embodiments.

The method 300 may begin with a first silicon-containing layer. The “first” silicon-containing layer may include a silicon substrate made substantially of silicon (e.g., greater than 98% silicon). In this case, the first silicon-containing layer may also be referred to as simply a silicon layer or a silicon substrate. Alternatively, the first silicon-containing layer may include a layer of silicon material formed over a substrate.

FIG. 4A illustrates an initial semiconductor structure for forming the memory array. Instead of using a traditional silicon-on-insulator (SOI) structure, such as a silicon-on-oxide structure, for forming the memory array, some embodiments may use a silicon substrate 402 as the underlying substrate. Previously, SOI structures were used as substrates for forming memory arrays in order for the oxide to act as an etch stop layer for both of the silicon etch processes. However, SOI wafers are generally more costly than silicon wafers, so it is advantageous to replace the SOI wafers with a cheaper material, such as a silicon substrate 402.

The method 300 may include forming a silicon germanium layer over a first silicon-containing layer (302). One of the advantages provided by the embodiments described herein is the ability to use the silicon substrate 402 combined with an optional silicon germanium (SiGe) layer 404 that may act as an etch stop for various etch processes when forming the DRAM. The silicon germanium layer 404 may optionally be formed over or above the first silicon-containing layer (e.g., the silicon substrate 402). In some embodiments, the silicon germanium layer 404 may optionally be formed directly on the silicon substrate 402 such that no other layers of materials are between the silicon germanium layer 404 and the silicon substrate 402. The silicon germanium layer 404 may have a thickness of between about 10 nm and about 20 nm, between about 20 nm and about 50 nm, between about 50 nm and about 70 nm, and/or between about 70 nm and about 80 nm. The thickness of the silicon germanium layer 404 may also be any combination of the ranges described above (e.g., between about 10 nm and about 80 nm) and/or any individual value in the ranges described above (e.g., about 50 nm). In other embodiments, the silicon germanium layer 404 may be omitted entirely. Therefore, the process flow described herein may also be compatible with a bare silicon substrate (with or without the SiGe layer), an SOI substrate, an implanted silicon substrate, a bonded substrate, and/or any other type of substrate. The germanium concentration in the silicon germanium layer 404 may be between about 5% and about 15%, between about 15% and about 30%, and/or between about 30% and about 40%.

The method 300 may further include forming a second silicon-containing layer over the silicon germanium layer (304). Another silicon layer 406 may be formed on top of the silicon germanium layer 404. This “second” silicon-containing layer may be formed from the same silicon material as the silicon substrate 402. For example, the silicon layer 406 may be substantially silicon. The thickness of the silicon layer 406 may also be substantially greater than the thickness of the silicon germanium layer 404. For example, the thickness of the silicon layer 406 may be 2 times greater, 5 times greater, 10 times greater, 20 times greater, or 50 times greater than the thickness of the silicon germanium layer 404. Alternatively, the silicon layer 406 may have a thickness of between about 100 nm and about 150 nm, between about 150 nm and about 200 nm, and/or between about 200 nm and about 250 nm. The thickness of the silicon layer 406 may also be any combination of the ranges described above (e.g., between about 100 nm and about 250 nm) and/or any individual value in the ranges described above (e.g., about 200 nm). In some embodiments, the silicon germanium layer 404 and/or the silicon layer 406 may be formed epitaxially.

In order to perform the shallow-trench-isolation (STI) etch, a hard mask 408 may be formed over the silicon layer 406. The hard mask 408 may be formed from any suitable material, including oxides, silicon nitride, silicon dioxide, polysilicon, carbon-containing materials, diamond-like carbon (TLC), and other suitable materials. The hard mask 408 may be formed using chemical vapor deposition (CVD), plasma-enhanced CVD (PECVD), or other suitable processes.

A pattern for the shallow trench isolation operation may be formed in the hard mask 408. For example, a pattern may be formed in the hard mask 408 by first applying a photoresist layer that may be spin-coated on top of the hard mask 408. A pattern may be formed in the photoresist corresponding to locations for the shallow trench isolation etch to be performed in the underlying silicon and silicon germanium layers. The pattern may be formed in the photoresist using techniques such as optical lithography to expose portions of the hard mask 408 where the trenches should be located. The pattern in the photoresist may then be transferred to the hard mask 408 directly or using additional layers, such as a dielectric anti-reflective coating (DARC), an amorphous carbon layer (ACL), and so forth. This operation is typically referred to as a hard mask open step. Any remaining photoresist and/or additional layers may then be removed using techniques such as oxygen plasma ashing, wet chemical stripping, and/or other similar processes.

The method 300 may also include etching an isolation trench between adjacent locations for DRAM devices in the DRAM structure (306). The isolation trench may be etched through the second silicon-containing layer, through the silicon germanium layer, and into the first silicon-containing layer. FIG. 4B illustrates a shallow-trench isolation (STI) etch performed on the semiconductor structure 400. An isolation trench is a key structural feature used to electrically isolate adjacent memory cells in the highly compact 4F2 layout. It is typically implemented using Shallow Trench Isolation (STI) to prevent leakage currents between neighboring cells while maintaining a small footprint required for high-density DRAM arrays.

Using the patterns in the hard mask 408 described above, isolation trenches 410 may be etched into the underlying silicon and silicon germanium layers. For example, to achieve high anisotropy, selectivity, and precise depth control, dry etch processes such as RIE may be used to create deep, narrow isolation trenches 410 with substantially vertical sidewalls. The depth of the isolation trenches 410 may be precisely controlled to penetrate entirely through the silicon layer 406 and into the silicon germanium layer 404. In some embodiments, the isolation trenches 410 may be etched entirely through the silicon germanium layer 404 and into the underlying silicon substrate 402. For example, the isolation trenches 410 may penetrate at least 5 nm into the silicon substrate 402 in order to provide a structural anchor for downstream processes described in detail below. The isolation trenches 410 may thus expose a portion of the silicon substrate 402 below the silicon germanium layer 404.

After forming the isolation trenches 410, the method 300 may further include forming an oxide in the isolation trench (308). The oxide may extend up from a bottom of the isolation trench, through the silicon germanium layer, and into the second silicon-containing layer. FIG. 4C illustrates a trench-fill process to fill at least a portion of the isolation trenches 410 with a fill material. For example, the isolation trenches 410 may be filled with a dielectric, such as SiO, SiN, SiON, SiCON, SiOC, SiCN, or other similar materials, using a deposition process, such as an atomic layer deposition (ALD) process or a chemical vapor deposition (CVD) process, to gap-fill the isolation trench 410 with a material such as silicon dioxide. As illustrated in FIG. 4C, the dielectric 412 may fill the isolation trenches 410 within the silicon substrate 402, the silicon germanium layer 404, the silicon layer 406, and the hard mask 408. The STI fill of the isolation trenches may also be bi-compositional, forming both a liner and a core. An overburden layer of the dielectric 412 may also be formed on top of the hard mask 408.

FIG. 4D illustrates the removal of a portion of the dielectric fill material from the isolation trenches 410. Optionally, the overburden of the dielectric 412 and/or the hard mask 408 may be removed using a chemical-mechanical polishing (CMP) process. Alternatively or additionally, one or more etch processes may be used that are selective to the dielectric 412 and/or the hard mask 408 to remove the dielectric 412 and/or the hard mask 408 while leaving the silicon material of the silicon layer 406 behind.

This etch process may be configured to leave at least a portion of the dielectric 412 at the bottom of the isolation trenches 410. More generally, this etch may be performed to remove the dielectric out of the isolation trenches 410, and the etch may be stopped before the dielectric 412 is below the second silicon-containing layer (e.g., the silicon layer 406). For example, the timing of the etch may be precisely controlled to stop the etch before removing all of the dielectric 412. As illustrated in FIG. 4D, the remaining portion of the dielectric 412 at the bottom of the isolation trenches 410 may extend down into the silicon substrate 402, through the silicon germanium layer 404, and up into the silicon layer 406. In other words, a top of the remaining portion of the dielectric 412 may extend above a top of the silicon germanium layer 404 to completely cover the exposed sidewalls of the silicon germanium layer 404. The remaining portion of the dielectric 412 may also cover at least a portion of the exposed sidewalls at the bottom of the silicon layer 406.

Some embodiments may use an alternative process to arrive at the semiconductor structure 400 illustrated in FIG. 4D. A bottom-up fill process may selectively deposit the dielectric 412 at the bottom of the isolation trench until the dielectric 412 extends above the silicon germanium layer 404. Turning back briefly to FIG. 4B, instead of completely filling the isolation trenches 410 with a fill material, some embodiments may instead perform the bottom-up fill to precisely form the dielectric 412 only at the bottom of the isolation trenches 410. The timing of this bottom-up fill may be controlled to form the dielectric 412 until the dielectric 412 extends above the top of the silicon germanium layer 404. The bottom-up fill process may result in the structure illustrated in FIG. 4D.

At this stage, the isolation trenches 410 have been completely formed, and the dielectric 412 has been deposited in the bottom of the isolation trenches 410. A second portion of the method 300 may optionally be continued to fill the isolation trenches 410 and perform a channel etch.

The method 300 may optionally be continued to include filling the isolation trench above the dielectric with a material with similar etch properties to silicon (310). More specifically, a fill material may be selected that can be etched with the silicon simultaneously, while also being capable of being removed separately from silicon in other downstream etch processes. For example, materials such as silicon germanium, doped silicon, and/or other similar materials and their mixtures may be used in this operation. As one nonlimiting example, this disclosure uses silicon germanium. However, it should be understood that other materials with similar etch properties may replace the silicon germanium without limitation in other embodiments.

FIG. 4E illustrates the isolation trenches 410 filled with silicon germanium. After forming the dielectric 412 at the bottom of the isolation trenches 410, the portion of the isolation trenches 410 above the dielectric 412 may be filled with a fill material, such as silicon germanium 416 or other similar materials. The silicon germanium 416 may be formed by deposition or other suitable processes to fill the remaining volume of the isolation trenches 410. For example, this fill process may involve a sidewall growth of silicon germanium on the sidewalls of the isolation trenches 410. Additionally, the silicon germanium 416 used to fill the isolation trenches 410 may have a different concentration of germanium compared to the silicon germanium layer 404 formed near the bottom of the isolation trenches 410. This may make subsequent steps in the DRAM process more readily able to distinguish between these two areas of silicon germanium if needed. For example, the difference in the concentration of germanium in the silicon germanium layer 404 and the silicon germanium 416 may be between about 5% and about 15%, between about 15% and about 30%, and/or between about 30% and about 40%. However, this is not necessary in all embodiments, and the silicon germanium layer 404 may also have the same concentration as the silicon germanium 416 used to fill the isolation trenches 410.

In some embodiments, an overburden of excess silicon germanium 416 may be formed on top of the silicon layer 406. Although not shown explicitly in FIG. 4E, this overburden may be removed through a CMP process and/or an etch-back (EB) process. For example, a plasma-based etch or a wet-chemical may be used in optional combination with a CMP process to remove any excess silicon germanium 416 extending above the top of the isolation trenches 410 and the top of the silicon layer 406. The result may be a substantially flat surface on top of the semiconductor structure 400. This step of removing any overburden is optional, and some processes may instead grow the silicon germanium 416 until it reaches the top of the isolation trenches 410 without forming any significant overburden.

The resulting semiconductor structure 400 may be primarily silicon-based. The only oxide in the semiconductor structure 400 may be the dielectric 412 at the bottom of the isolation trenches 410. This also represents a significant reduction in the amount of oxide in the semiconductor structure 400 compared to previous techniques. The dielectric 412 effectively separates the silicon of the silicon substrate 402 from the silicon layer 406. The dielectric 412 also effectively separates the silicon germanium layer 404 from the silicon germanium 416 used to fill the isolation trenches 410. Therefore, removal of any of these layers can use etches that are selective to either silicon or silicon germanium, depending on the layer to be removed. This eliminates or greatly reduces the need for any silicon oxide etches.

The method 300 may optionally be further continued to include performing a back gate etch to form a back gate trench that is orthogonal to the isolation trench (312). FIG. 4F illustrates results of a back gate etch that may performed on the silicon structure. The back gate etch is performed to expose the back gate region and to expose the dielectric 412. In this example, the semiconductor structure 400 may include additional layers formed on top of the silicon layer 406. For example, a thin pad oxide 418 may first be formed, followed by a sacrificial silicon nitride layer 420, followed by a silicon oxide hard mask 424. The silicon oxide hard mask 424 may be patterned to define the trenches for the back gate etch using the patterning process described above. An etch process may then be performed to etch through the sacrificial silicon nitride layer 420, the pad oxide 418, the silicon layer 406, the silicon germanium 416 in the trenches, and the silicon germanium layer 404. In some embodiments, the etch may be selective such that the silicon and the silicon germanium are etched while leaving the dielectric 412 near the bottom of the semiconductor structure 400. The etch may also be directional to result in a back gate region that has substantially straight sidewalls with very little taper.

As illustrated in FIG. 4F, the back gate etch should not remove the dielectric 412 where the back gate trench 427 intersects with the isolation trench. The back gate etch may extend at least down to a bottom of the silicon germanium layer 404. In some embodiments, the depth of the etch may extend to below a bottom surface of the silicon germanium layer 404. In other words, the etch may extend completely through the silicon germanium layer 404 to expose the underlying silicon substrate 402. The depth of the etch may also be above or at the bottom level of the dielectric 412. For example, the depth of the trenches 427 may be above the bottom of the dielectric 412 such that the portion of the silicon substrate 402 beneath the dielectric 412 is not exposed.

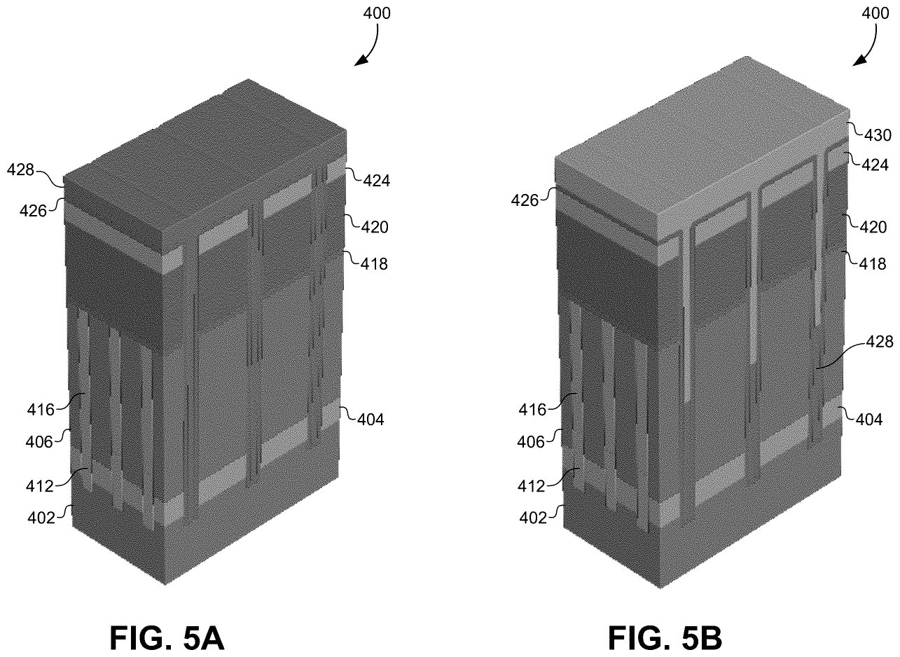

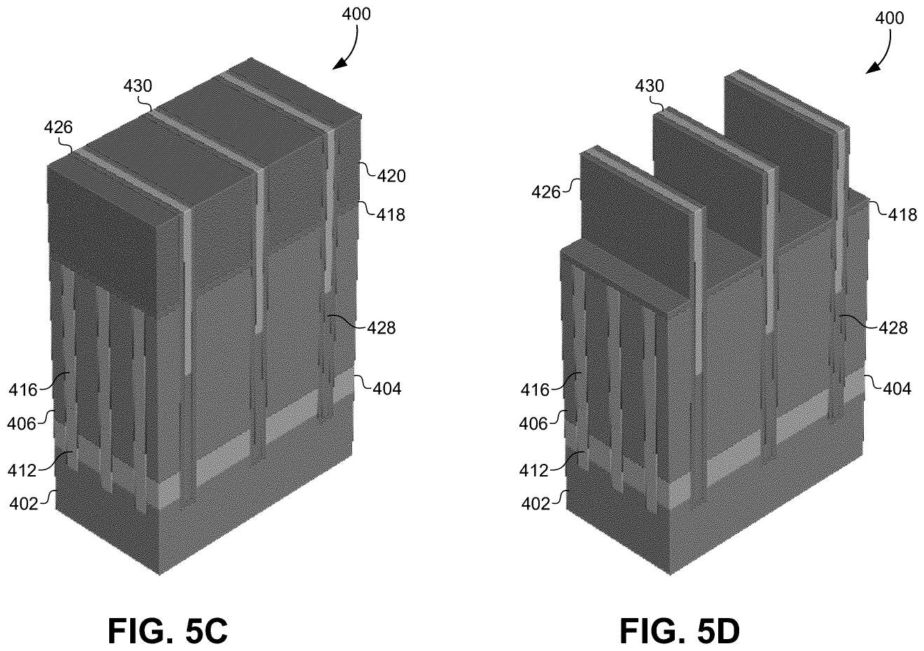

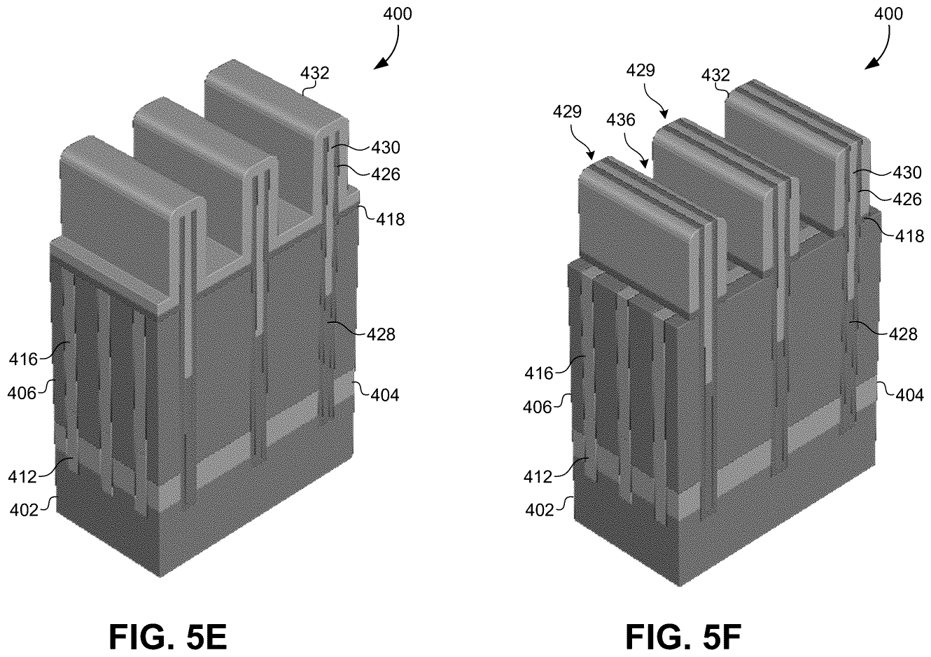

At this stage, standard techniques may be used for forming the back gate region in the semiconductor structure 400. FIGS. 5A-5F illustrate incremental structures to form the back gate region, according to some embodiments. These processes are fully compatible with the semiconductor structure 400 illustrated in FIGS. 4A-4F. These processes may also be compatible with other existing techniques not utilizing the silicon germanium layer 404 or the dielectric 412.

FIG. 5A illustrates how the back gate regions of the semiconductor structure 400 may be filled with a silicon oxide liner (i.e. a gate oxide (GOX) for the DRAM back gate) and a back gate metal. For example, a silicon oxide liner 426 may first be formed in the back gate trenches 427. For example, an atomic layer deposition (ALD) process may be used to grow a layer of silicon oxide along the sidewalls and bottom of the trenches 427. The silicon oxide liner 426 may also be formed on top of the remaining hard mask 424. Alternatively, the silicon oxide liner 426 for the gate oxide may be replaced with an air gap. For example, a dummy fill may be used at this stage which may be replaced in downstream processes. The dummy fill may later be fully removed downstream without a backfill in order to form an air gap.

In some embodiments, a low temperature anneal may also be performed. Embodiments using the silicon germanium layer 404 may not be compatible with higher temperature anneal processes, since higher temperatures may cause the silicon germanium to diffuse. Therefore, this anneal process may be performed at temperatures less than or about 600° C., less than or about 700° C., less than or about 800° C., less than or about 900° C., or less than or about 1000° C., depending on the process parameters and materials used. After the silicon oxide liner 426 is annealed, the back gate trenches 427 may then be filled with a back gate metal 428. The gate metal 428 may substantially fill the trenches 427 without any significant seams or voids. The back gate metal 428 may also result in an overburdened of the back gate metal 428 being formed on top of the semiconductor structure 400 as illustrated in FIG. 5A.

FIG. 5B illustrates how the back gate metal 428 can be recessed and covered with an dielectric plug (e.g., SiO). In some embodiments, a CMP or etch process may be applied to the semiconductor structure 400 in FIG. 5A to remove the overburden of the gate metal 428. The back gate metal 428 may thus be recessed from the back gate trenches 427 until only a portion of the back gate metal 428 remains at the bottom of the back gate trenches 427. As illustrated in FIG. 5B, the height of the back gate metal 428 may extend from the bottom of the trench up to a level above the top surface of the dielectric 412. The timing of this etch process may be controlled to remove a precise amount of the back gate metal 428 until a predetermined height is reached.

After recessing the back gate metal 428, a dielectric 430 may be formed on the semiconductor structure 400. This dielectric 430 may fill the top portion of the trenches above the back gate metal 428. An overburdened of the dielectric 430 may be formed on top of the semiconductor structure as illustrated in FIG. 5B.

FIG. 5C illustrates the removal of the top portions of the semiconductor structure 400. For example, a CMP process may be used to polish away layers at the top of the semiconductor structure 400 until the overburden of the dielectric 430 is removed, along with top exposed dielectric 426, and the remaining hard mask 424. As illustrated in FIG. 5C, this may expose the portion of the dielectric 430 remaining in the trenches and the liner 426. This CMP process may stop before removing a substantial amount of the sacrificial silicon nitride layer 420 and before reaching the pad oxide 418.

FIG. 5D illustrates the removal of the sacrificial silicon nitride layer 420, which may be performed using any suitable etch process that is selective to remove the silicon nitride layer 420 without significantly removing the dielectric of the liner 426 or the dielectric 430.

FIG. 5E illustrates the formation of a liner 432 over the exposed surfaces on top of the semiconductor structure 400. The liner 432 may be a liner-type silicon-etch hard mask, which may be formed from SiO, SiN, SiON, SiOC, SiCN, SiOCN, carbon, BC, WBC, WC, and/or other similar materials. In this example, the liner 432 may be formed from the same material as the dielectric 430. The liner 432 may be formed conformally around the exposed features on top of the semiconductor structure 400 using an ALD or CVD process or other similar technique.

FIG. 5F illustrates the bottom-punch etch of the liner 432. For example, masks, directional etches, and other techniques may be used to remove a portion of the liner 432 in the spaces 436 between the gate regions 429. Additionally, the portion of the pad oxide 418 may also be removed from the spaces 436 between the gate regions 429. The etch process may be selective such that the oxides are removed while leaving the silicon layer 406 and the silicon germanium 416 intact, thereby exposing these layers. In some implementations, the silicon and/or silicon germanium layers may be used as an etch stop layer.

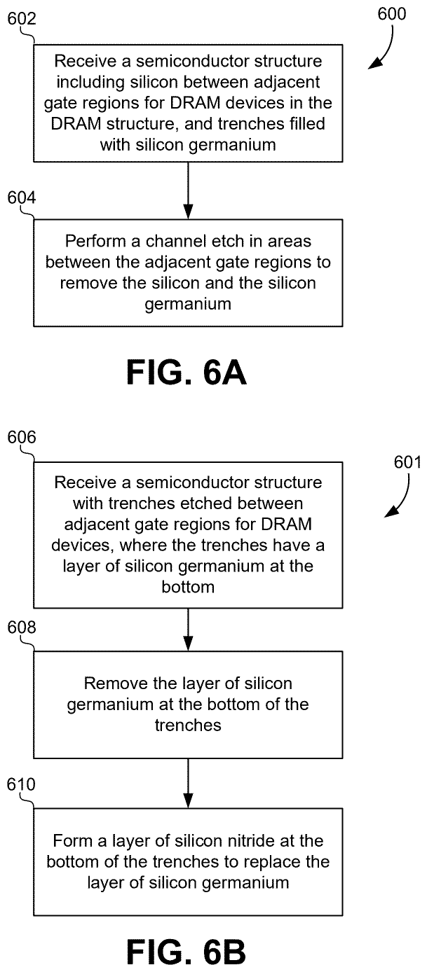

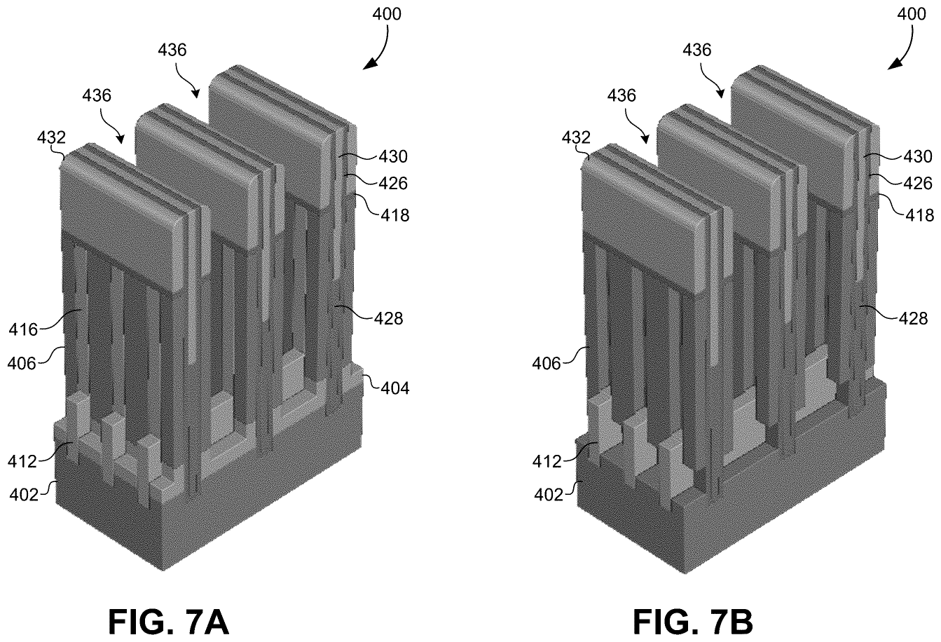

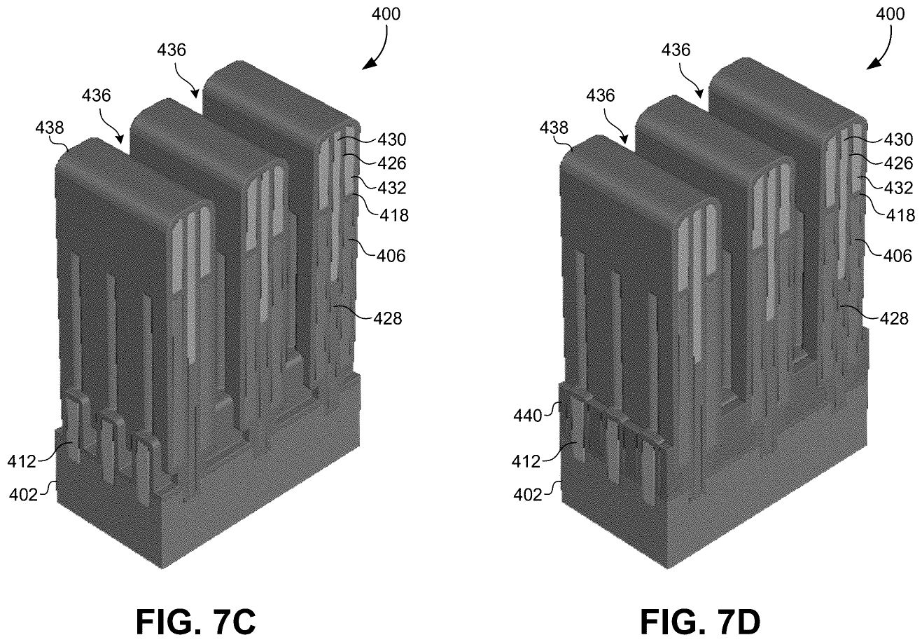

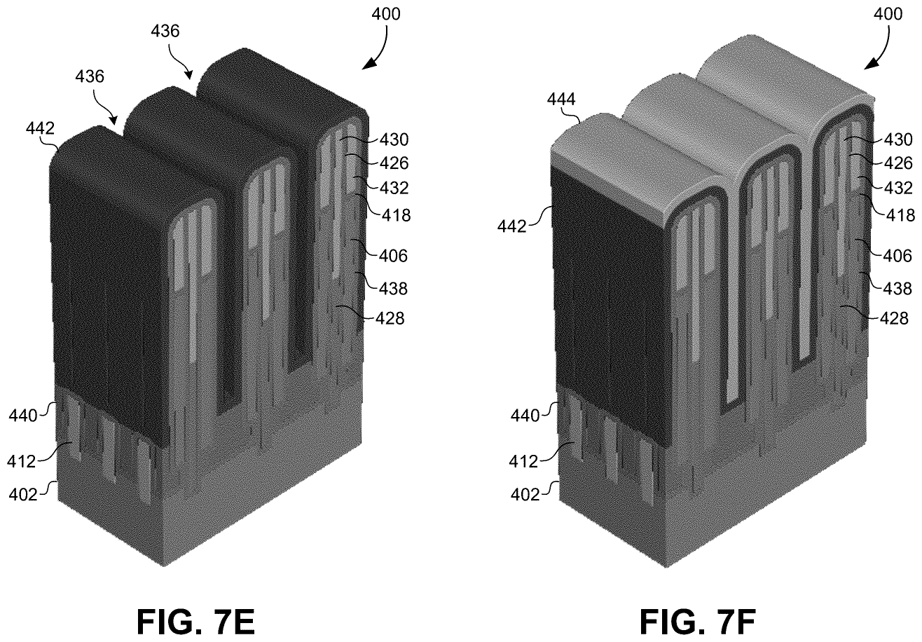

At this stage, the traditional process of forming the 4F2 DRAM structures may again be altered to take advantage of the silicon germanium and oxide materials formed according to method 300 above. FIG. 6A illustrates a flowchart of a method 600 for further forming a DRAM structure, according to some embodiments. FIGS. 7A-7F illustrate example incremental structures to finish forming the gate region, according to some embodiments. Each of these example incremental structures may result from carrying out specific operations in method 600 described above. However, the operations of method 600 may be broader than the specific structures illustrated in FIGS. 7A-7F, and thus these figures should be used only as non-limiting examples.

Since each of the operations illustrated by the figures (e.g., deposition, etch, polishing, etc.) may be considered separate operations, the method 600 may begin by receiving the semiconductor structure 400 illustrated in FIG. 5F. More generally, the method 600 may include receiving a semiconductor structure including silicon between adjacent gate regions for DRAM devices in the DRAM structure, where the silicon may include trenches filled at least in part with silicon germanium (602).

The method 600 may also include performing a channel etch in areas between the adjacent gate regions to remove the silicon and the silicon germanium(604). FIG. 7A illustrates a channel etch that may be used to remove a portion of the silicon and silicon germanium layers. The etch may be a directional etch that etches vertically down into the spaces 436 between the gate regions. For example, the etch may remove the exposed portion of the silicon-containing layer 406 completely while leaving the unexposed portion of the silicon 406 that is underneath the remaining pad oxide 418 and/or the silicon oxide liner 432 of the spacer material. The dielectric 412 is not significantly removed by the etch process. The depth of this etch may penetrate the silicon germanium layer 404 to some depth. For example, the depth of the etch may etch into the silicon germanium layer 404 without etching into the underlying silicon substrate 402. Therefore, at least a portion of the silicon germanium layer 404 may remain after the etch is complete. In some embodiments, the etch may penetrate down to the bottom of the silicon germanium layer 404 without significantly penetrating the silicon substrate 402. Alternatively, the etch may penetrate down to expose a top of the silicon germanium layer 404 without significantly penetrating the silicon germanium layer 404.

As described above, the concentration of germanium in the silicon germanium layer 404 compared to the concentration in the silicon germanium 416 may be different. Specifically, the etch rate of silicon germanium can vary depending on the germanium concentration. This concentration may be used to selectively etch the silicon germanium 416 while using the silicon germanium layer 404 as an etch stop. In this case, an etch stop signal can be detected upon the exposure of the silicon germanium layer 404. Alternatively, the same concentration may be used in these two silicon germanium regions, and the timing of the etch may be used to stop the etch after the etch has penetrated the silicon germanium layer 404. In this case, the etch may be allowed to penetrate into the silicon germanium layer 404 without completely etching through the silicon germanium layer 404.

The thickness of the silicon germanium layer 404 may provide a buffer for the loading effect. The loading effect may refer to uneven channel depths that may be etched into the semiconductor structure 400, which may lead to inconsistent electrical properties in the DRAM array. As long as the etch penetrates down to the silicon germanium layer 404, this process allows for slight variations in the depth of the channel etch across the DRAM array. As will be described below, the removal of the rest of the silicon germanium layer 404 may ensure that the channel depth is consistent across the substrate. Additionally, the dielectric 412 may remain intact to act as an anchor for the layers of the semiconductor structure 400 above the dielectric 412 as described further below.

This channel etch may be greatly simplified and improved compared to existing techniques. For example, the etch may be automatically aligned with the oxide spacers formed by the silicon oxide liner 432. Thus, the silicon and/or silicon germanium only needs to be etched in a single direction in the spaces 436 exposed by the gate structures. For example, previous solutions would need to etch in both the X and Y horizontal directions, and the process needed to ensure that the etch was optimized and aligned in both directions. In contrast, this technique only needs to etch in a single Y direction. Compared to previous techniques, the removal of the silicon germanium eliminates the need to remove a silicon stringer based on the geometry of this semiconductor structure 400.

Second, this etch does not need to etch both oxide and silicon at the same time. Instead, the etch process can be selective to etch only the silicon and/or silicon germanium, while leaving the silicon oxide intact. Generally, etching silicon and silicon germanium together while preserving silicon oxide is easier than etching silicon and silicon oxide together. This simplifies the etch process and allows the directional acts to be much more precise when removing the silicon and silicon germanium. For example, HBr/Cl₂/O₂-based plasma etches may be used for anisotropic etching of both silicon and silicon germanium while having high selectivity to silicon oxide. These techniques also simplify the selection and formation of the hard mask. Generally, it is difficult to use a liner-type of hard mask that is selective to both silicon and silicon oxide. In comparison, it is relatively easy to select and form a liner-type hard mask that is selective to only silicon.

FIG. 6B illustrates a method 601 for forming at least a portion of a DRAM structure, according to some embodiments. The method 601 may include receiving a semiconductor structure that includes trenches etched between adjacent gate regions for DRAM devices in the DRAM structure, where the trenches may include a layer of silicon germanium at a bottom of the trenches (606). By way of example, the method 601 may begin with the semiconductor structure 400 illustrated in FIG. 7A. However, this semiconductor structure 400 is not meant to be limiting, and the method 601 may be compatible with other structures that include more or fewer features than those illustrated in FIG. 7A.

The method 601 may also include removing the layer of silicon germanium at the bottom of the trenches (608). FIG. 7B illustrates the removal of the silicon germanium layer 404. An etch, such as an isotropic dry etch or a wet etch may be used to remove any remaining silicon germanium in the semiconductor structure 400. For example, the remaining silicon germanium 416 underneath the oxide 430 may be removed, along with the remaining silicon germanium layer 404 at the bottom of the channel regions. Removing the silicon germanium layer 404 ensures a consistent depth in the spaces 436 between the gate structures, since this layer was formed on the level silicon substrate 402 in the early processing stages.

Additionally, the dielectric 412 that was formed earlier in the process now provides structural support for the semiconductor structure 400. Specifically, since the silicon germanium layer 404 is removed from underneath the gate regions, the overlying gate regions may be unstable without the dielectric 412. However, the dielectric 412 provides a structural support for the gate regions by tying these regions more securely to the silicon substrate 402 after the silicon germanium layer 404 has been removed.

FIG. 7C illustrates the formation of a gate oxide. The gate oxide 438 may be formed conformally on the exposed surfaces of the semiconductor structure 400. For example, an ALD process may be used to conformally coat the exposed surfaces of the semiconductor structure 400 with a gate oxide 438, such as silicon oxide. Alternatively, the formation of the gate oxide 438 may be performed later. For example, the stop layer 440 described below may be formed before the gate oxide 438 in some embodiments.

The method 601 may further include forming a layer of silicon nitride at the bottom of the trenches to replace the layer of silicon germanium (610). FIG. 7D illustrates a bottom-up fill of a stop layer 440. The stop layer 440 may be formed in a bottom-up process as described above to selectively deposit the stop layer 440 at the bottom of the spaces 436 in the semiconductor structure 400. Note that some embodiments may leave the silicon germanium layer 404 in place and forgo the formation of the stop layer 440. However, the stop layer 440 provides a stronger support surface. The stop layer 440 may also act as an etch stop layer when the semiconductor structure 400 is flipped over and polished during later stages of the 4F2 DRAM process.

In some embodiments, silicon nitride may be used as a stop layer 440. More generally, any material may be used that provides a “hard” etch stop layer compared to the “soft” etch stop layer provided by silicon germanium. For example, the stop layer 440 may be characterized as non-diffusing in comparison to the germanium in silicon germanium. The stop layer 440 may also be characterized as compatible with both a wet etch and a CMP process, whereas silicon germanium may typically function best as a wet etch stop layer. Additionally, a stop layer 440 such as silicon nitride may be consumed very little during the etch, so a thinner layer of the stop layer 440 may be used in comparison to a layer of silicon germanium, which may be consumed more by the etch process. Using a thinner stop layer 440 means that a thinner silicon germanium layer 404 may be used in the first place, which reduces defects in the surrounding silicon. Additionally, replacing the silicon germanium layer 404 with the stop layer 440 eliminates silicon germanium from the semiconductor structure 400, which in turn allows for higher temperature process is to be used without concern for diffusing the germanium into the surrounding layers. For example, the process for forming the gate oxide 438 in FIG. 7C may use higher temperatures that may not be compatible with silicon germanium.

FIG. 7E illustrates the deposition of the gate metal 442 on the exposed surfaces of the semiconductor structure 400. The gate metal 442 may be formed conformally on the exposed surfaces. The gate metal 442 may include any suitable metal, such as titanium nitride, tungsten, Mo, TiSiN, MoN, and/or other similar materials and their combinations.

FIG. 7F illustrates the formation of a gate isolation layer 444. The gate isolation layer 444 may fill the remaining spaces 436 between the gate structures and may cover the gate structures as illustrated. The gate isolation layer 444 may be formed using an oxide or any dielectric/insulating material. Alternatively, an airgap may be used in place of the gate isolation layer 444.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of forming a DRAM structure, the method comprising:
forming a silicon germanium layer over a first silicon-containing layer;
forming a second silicon-containing layer over the silicon germanium layer;
etching an isolation trench between adjacent locations for DRAM devices in the DRAM structure, wherein the isolation trench is etched through the second silicon-containing layer, through the silicon germanium layer, and into the first silicon-containing layer; and
forming a dielectric in the isolation trench, wherein the dielectric extends up from a bottom of the isolation trench, through the silicon germanium layer, and into the second silicon-containing layer.

2. The method of claim 1, wherein the first silicon-containing layer comprises a silicon substrate.

3. The method of claim 1, wherein forming the dielectric in the isolation trench comprises using a chemical vapor deposition (CVD) process to gap-fill the isolation trench with silicon dioxide.

4. The method of claim 3, wherein forming the dielectric in the isolation trench further comprises performing an etch to remove the dielectric out of the isolation trench, and stopping the etch before the dielectric is below the second silicon-containing layer.

5. The method of claim 1, wherein forming the dielectric in the isolation trench comprises using a bottom-up fill process to selectively deposit the dielectric at the bottom of the isolation trench until the dielectric extends above the silicon germanium layer.

6. The method of claim 1, further comprising, after forming the dielectric in the isolation trench, filling the isolation trench above the oxide with silicon germanium.

7. The method of claim 6, wherein a concentration of germanium in the silicon germanium filling the isolation trench above the oxide is different from a concentration of germanium in the silicon germanium layer.

8. The method of claim 6, further comprising, after filling the isolation trenches above the dielectric with silicon germanium, performing a back gate etch to form a back gate trench that is orthogonal to the isolation trench.

9. The method of claim 8, wherein the back gate etch does not remove the dielectric where the back gate trench intersects with the isolation trench.

10. The method of claim 8, wherein the back gate etch extends at least down to a bottom of the silicon germanium layer.

11. A method of forming a DRAM structure, the method comprising:
receiving a semiconductor structure comprising silicon between adjacent gate regions for DRAM devices in the DRAM structure, wherein the silicon comprises trenches filled at least in part with silicon germanium; and
performing a channel etch in areas between the adjacent gate regions to remove the silicon and the silicon germanium.

12. The method of claim 11, wherein the trenches are also filled at least in part with a dielectric at a bottom of the trenches, and the silicon germanium fills a remaining portion of the trenches above the dielectric at the bottom of the trenches.

13. The method of claim 11, wherein the semiconductor structure further comprises a layer of silicon germanium orthogonal to the trenches and proximate to a bottom of the trenches.

14. The method of claim 13, wherein the layer of silicon germanium that is orthogonal to the trenches comprises a different germanium concentration than the silicon germanium that fills the trenches, such that the layer of silicon germanium acts as an etch stop when performing the channel etch.

15. The method of claim 13, further comprising:
removing the layer of silicon germanium; and
forming a layer of silicon nitride to replace the layer of silicon germanium.

16. A method of forming a DRAM structure, the method comprising:
receiving a semiconductor structure comprising trenches etched between adjacent gate regions for DRAM devices in the DRAM structure, wherein the trenches comprise a layer of silicon germanium at a bottom of the trenches;
removing the layer of silicon germanium at the bottom of the trenches; and
forming a stop layer at the bottom of the trenches to replace the layer of silicon germanium.

17. The method of claim 16, further comprising:
removing a silicon substrate underneath the stop layer, wherein the stop layer acts as a stop layer for a process that removes the silicon substrate, and the stop layer comprises silicon nitride.

18. The method of claim 16, wherein the semiconductor structure further comprises a dielectric at the bottom of the trenches, wherein the dielectric provides a structural support for the adjacent gate regions when the layer of silicon germanium is removed.

19. The method of claim 16, wherein removing the layer of silicon germanium at the bottom of the trenches further comprises also removing silicon germanium under the gate regions using a wet etch process or an isotropic dry etch process.

20. The method of claim 16, wherein forming the stop layer at the bottom of the trenches comprises:
conformally forming a gate oxide on exposed areas of the semiconductor structure; and
performing a bottom-up fill process to selectively form the stop layer only at the bottom of the trenches over or under the gate oxide.
